(19) United States
(12) Patent Application Publication
(10) Pub. No.: US 2026/0123216 A1
(43) Pub. Date: Apr. 30, 2026

(54) DISPLAY APPARATUS

(71) Applicant: Samsung Electronics Co., Ltd., Suwon-si (KR)

(72) Inventors: Yoohwan KIM, Suwon-si (KR); Daehee LEE, Suwon-si (KR); Seungjun JEONG, Suwon-si (KR)

(73) Assignee: Samsung Electronics Co., Ltd., Suwon-si (KR)

(21) Appl. No.: 19/361,928

(22) Filed: Oct. 17, 2025

Related U.S. Application Data
(63) Continuation of application No. PCT/KR2025/095531, filed on Sep. 1, 2025.

(30) Foreign Application Priority Data
Oct. 24, 2024 (KR) 10-2024-0146359

(51) Int. Cl. H10K 59/131; H10K 59/80

(52) U.S. Cl. CPC H10K 59/131; H10K 59/875

(57) ABSTRACT

A display apparatus includes a substrate; a pixel disposed on the substrate, the pixel including a first sub-pixel, a second sub-pixel, a third sub-pixel, and a fourth sub-pixel that are spaced apart from each other in a first direction; a wiring disposed on the substrate at a side of at least one sub-pixel of the first sub-pixel, the second sub-pixel, the third sub-pixel, and the fourth sub-pixel; and a light slit formed at the side of the at least one sub-pixel and through which a light of the at least one sub-pixel is configured to be emitted by the light being passed through a slit portion formed in the wiring.

### CROSS-REFERENCE TO RELATED APPLICATIONS

This application is a continuation of International Application No. PCT/KR2025/095531, filed on September 1, 2025, which is based on and claims priority to Korean Patent Application No. 10-2024-0146359, filed on October 24, 2024, in the Korean Intellectual Property Office, the disclosures of which are incorporated by reference herein in their entireties.

### BACKGROUND

### 1. Field

The disclosure relates to a display apparatus.

### 3. Description of Related Art

A display apparatus is a type of output device configured to convert acquired or stored electrical information to visual information and display the visual information to a user.

Display apparatuses include a monitor device connected to a personal computer, a server computer, or the like, a portable computer device, a navigation terminal device, a general television device, an Internet protocol television (IPTV) device, a portable terminal device such as a smart phone, a tablet PC, a personal digital assistant (PDA), a cellular phone, or the like, various display apparatuses used to reproduce an image such as an advertisement or a movie in an industrial field, various other audio/video systems, or the like.

In general, the color of light emitted from a display apparatus may vary depending on the viewing angle. In other words, a display apparatus may exhibit color shift according to the viewing angle.

### SUMMARY

One or more embodiments of the present disclosure provide a display apparatus that reduces color shift depending on the viewing angle by including a light slit.

Further, one or more embodiments of the present of the present disclosure provide a display apparatus in which a wiring disposed between sub-pixels is divided into two separated wiring portions, thereby forming a light slit between the two wiring portions.

The technical objectives of the present disclosure are not limited to the above, and other objectives that are not described above will be clearly understood by those skilled in the art from the above detailed description.

According to an aspect of the disclosure, a display apparatus includes: a substrate; a pixel disposed on the substrate, the pixel including a first sub-pixel, a second sub-pixel, a third sub-pixel, and a fourth sub-pixel that are spaced apart from each other in a first direction; a wiring disposed on the substrate at a side of at least one sub-pixel of the first sub-pixel, the second sub-pixel, the third sub-pixel, and the fourth sub-pixel; and a light slit formed at the side of the at least one sub-pixel and through which a light of the at least one sub-pixel is configured to be emitted by the light being passed through a slit portion formed in the wiring.

According to an aspect of the disclosure, a display apparatus includes: a substrate; a wiring disposed on the substrate and including a slit portion; an interlayer insulating layer disposed on the substrate and covering the wiring; a planarization layer disposed on the interlayer insulating layer; an anode electrode disposed on the planarization layer; a pixel defining layer covering an edge of the anode electrode and an adjacent edge of the planarization layer; an organic light emitting layer disposed on the anode electrode and the pixel defining layer; a cathode electrode disposed on the organic light emitting layer; and a light slit configured to pass light through a slit portion of the wiring and the substrate.

### BRIEF DESCRIPTION OF THE DRAWINGS

The above and other aspects, features, and advantages of specific embodiments of the present disclosure will be more apparent from the following description with reference to the accompanying drawings, in which:

FIG. 1 illustrates a display apparatus according to one or more embodiments,

FIG. 2 is a schematic view illustrating a structure of the display apparatus according to one or more embodiments,

FIG. 3 is an enlarged view of a pixel of the display apparatus according to one or more embodiments,

FIG. 4 is a cross-sectional view taken along the line A–A′ of FIG. 3,

FIG. 5 is an enlarged view of a pixel of the display apparatus according to one or more embodiments,

FIG. 6 is a cross-sectional view taken along the line B–B′ of FIG. 5,

FIG. 7 is an enlarged view of a pixel of the display apparatus according to one or more embodiments,

FIG. 8 is a cross-sectional view taken along the line C–C′ of FIG. 7,

FIG. 9 is an enlarged view of a pixel of the display apparatus according to one or more embodiments,

FIG. 10 is a cross-sectional view taken along the line D–D′ of FIG. 9, and

FIG. 11 is an enlarged view of a pixel of the display apparatus according to one or more embodiments.

### DETAILED DESCRIPTION

Various embodiments of the disclosure and terms used herein are not intended to limit the technical features described herein to specific embodiments, and should be understood to include various modifications, equivalents, or substitutions of the corresponding embodiments.

In describing of the drawings, similar reference numerals may be used for similar or related elements.

The singular form of a noun corresponding to an item may include one or more of the items unless clearly indicated otherwise in a related context.

In the disclosure, phrases, such as “A or B”, “at least one of A and B”, “at least one of A or B”, “A, B or C”, “at least one of A, B and C”, and “at least one of A, B, or C” may include any one or all possible combinations of the items listed together in the corresponding phrase among the phrases.

Terms such as “unit”, “module”, and “member” may be implemented in hardware, software, or a combination thereof. In some embodiments, a plurality of such “units”, “modules”, or “members” may be implemented as a single component, or a single “unit”, “module”, or “member” may include a plurality of components.

Terms used in this specification are for the purpose of describing embodiments and are not intended to limit the invention. The singular forms include plural references unless the context clearly indicates otherwise. As used herein, the terms “comprise” and “have” are intended to specify the presence of stated features, integers, steps, operations, elements, and/or components but do not preclude the presence or addition of one or more other features, integers, steps, operations, elements, components, and/or combinations thereof.

Terms such as “1st”, “2nd”, “primary”, or “secondary” may be used simply to distinguish an element from other elements, without limiting the element in other aspects (e.g., importance or order).

As used herein, the term “and/or” includes any and all combinations of one or more of the associated listed items.

When an element (e.g., a first element) is referred to as being “(functionally or communicatively) coupled” or “connected” to another element (e.g., a second element), the first element may be connected to the second element, directly (e.g., wired), wirelessly, or through a third element.

When a given element is referred to as being “connected to”, “coupled to”, “supported by” or “in contact with” another element, it is to be understood that it may be directly or indirectly connected to, coupled to, supported by, or in contact with the other element. When a given element is indirectly connected to, coupled to, supported by, or in contact with another element, it is to be understood that it may be connected to, coupled to, supported by, or in contact with the other element through a third element.

It will also be understood that when an element is referred to as being “on” another element, it may be directly on the other element or intervening elements may also be present.

Meanwhile, directional terms such as “upper”, “lower”, “front”, or “rear” are defined based on the accompanying drawings and are not intended to limit the actual orientation or position of components. For instance, “front” and “rear” may correspond to +X and –X directions, and “upward” and “downward” may correspond to +Z and –Z directions in the drawings. Similarly, “left” and “right” may correspond to +Y and –Y directions. However, depending on the drawing, these directions may be reversed.

Hereinafter, various embodiments of the disclosure will be described in detail with reference to the accompanying drawings.

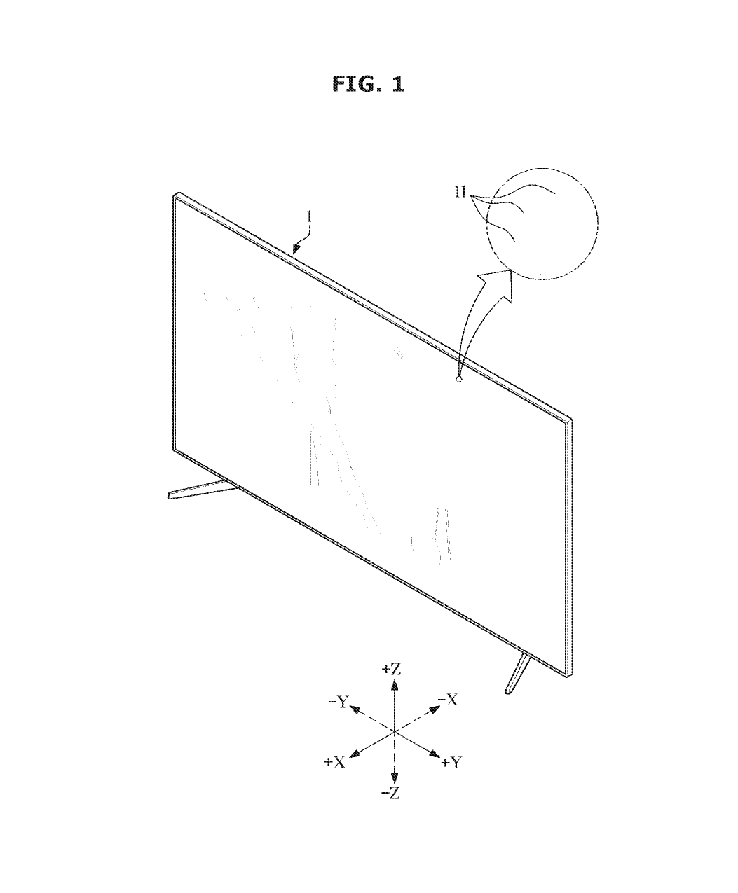

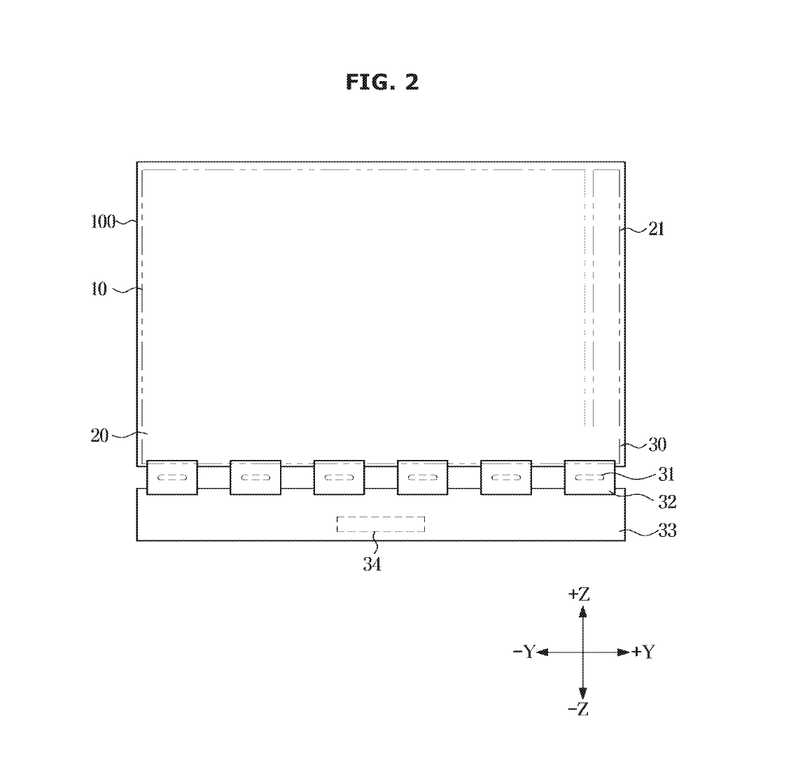

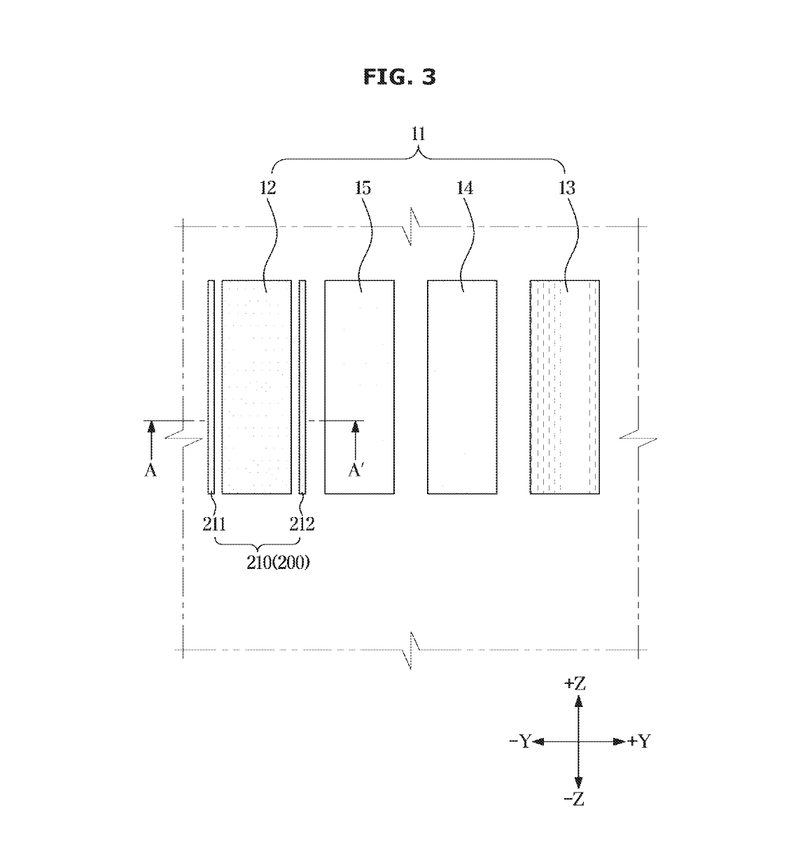

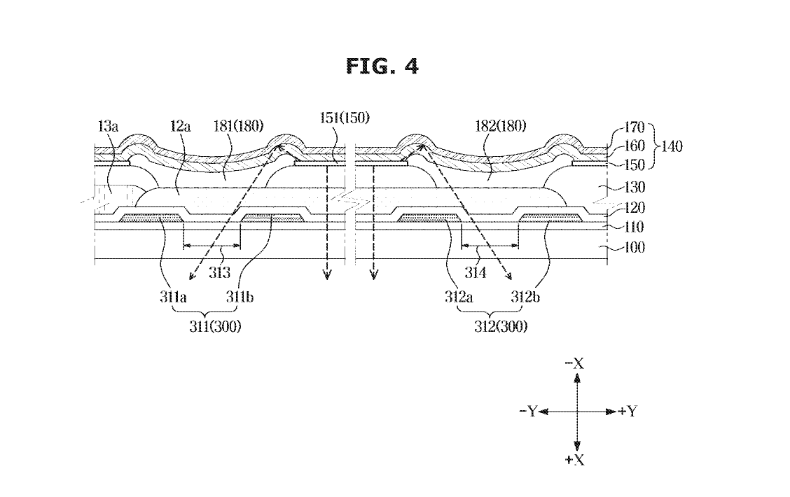

FIG. 1 illustrates a display apparatus according to one or more embodiments, and FIG. 2 is a schematic view illustrating a structure of the display apparatus according to one or more embodiments, and FIG. 3 is an enlarged view of a pixel of the display apparatus according to one or more embodiments, and FIG. 4 is a cross-sectional view taken along the line A–A′ of FIG. 3.

Referring to FIG. 1, the display apparatus 1 according to one or more embodiments of the present disclosure may be applied to a smartphone, mobile phone, tablet PC, PDA, portable multimedia player (PMP), television, game console, wristwatch-type electronic device, head-mounted display, monitor of a personal computer, notebook computer, car navigation system, automobile instrument panel, digital camera, camcorder, external advertisement board, electronic display board, medical device, inspection device, home appliances such as a refrigerator or washing machine, or an Internet of Things (IoT) device.

The display apparatus 1 according to one or more embodiments may include an organic light emitting display (OLED). However, it is not limited thereto, and the display apparatus may include at least one of an inorganic electroluminescence (inorganic EL) display, a quantum dot display (QED), or a micro light emitting diode (micro-LED) display. In the following description, an OLED display is provided as an example, but it will be understood that the scope of the invention also covers other display types such as inorganic EL, QED, and micro-LED displays.

Referring to FIG. 2, the display apparatus 1 may include a substrate 100, a driving unit 21, a pad unit 30, a driving integrated circuit (IC) 31, a connection part 32, a circuit board 33, and a timing controller 34.

The substrate 100 may be a rigid substrate or a flexible substrate capable of bending, folding, or rolling. The substrate 100 may include an insulating material such as glass, quartz, or a polymer resin. Examples of the polymer materials include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or combinations thereof. The substrate 100 may also include a metal material.

The substrate 100 may be divided into a display area 10 and a non-display area 20. The display area 10 may refer to a region where images are displayed, and the non-display area 20 may refer to a region where no images are displayed.

The display area 10 may have a square or rectangular shape, but is not limited thereto. The non-display area 20 may be disposed around the display area 10 and may completely or partially surround it. The non-display area 20 may have a frame shape with four edges surrounding the display area 10 and may form the bezel of the display apparatus 1.

Although the display area 10 may refer to most of the central region of the substrate 100, it is not limited thereto. A plurality of pixels 11, scan lines or gate lines, and data lines may be disposed in the display area 10.

The non-display area 20, which does not display images, may be defined at the edge of the substrate 100 to surround all or part of the display area 10. The driving unit 21 and the pad unit 30 may be formed in the non-display area 20.

The driving unit 21 may supply scan signals or gate signals to the scan lines in response to gate control signals input through the pad unit 30 from the timing controller 34. The driving unit 21 may be disposed in the non-display area 20 located at one side of the display area 10 of the substrate 100. According to one or more embodiments, the driving unit 21 may be implemented in a gate driver in panel (GIP) method in the non-display area 20.

The pad unit 30 may be disposed in the non-display area 20 at a lower side of the substrate 100. The pad unit 30 may include data pads connected to data lines, drive current pads connected to drive current lines, and potential pads to which a voltage is applied.

The driving IC 31 may receive digital video data and source control signals from the timing controller 34. The driving IC 31 may convert the digital video data into analog data voltages according to the source control signals and supply them to the data lines. When implemented as a chip, the driving IC 31 may be mounted on the connection part 32 using chip-on-film (COF) or chip-on-plastic (COP) techniques.

The connection part 32 may electrically connect the pad unit 30 and the circuit board 33. The connection part 32 may include a flexible printed circuit board (FPCB). Wirings for connecting the pad unit 30 and the driving IC 31 or the pad unit 30 and the circuit board 33 may be formed in the connection part 32. According to one or more embodiments, the connection part 32 may be attached to the pad unit 30 using an anisotropic conductive film (ACF), allowing the wirings of the pad unit 30 and the connection part 32 to be connected.

The circuit board 33 may be attached to the connection part 32. A plurality of circuits implemented with drive chips may be mounted on the circuit board 33. For example, the timing controller 34 may be mounted on the circuit board 33. The circuit board 33 may be a printed circuit board (PCB) or a flexible PCB.

The timing controller 34 may receive digital video data and timing signals from an external system board through the circuit board 33. Based on the timing signals, the timing controller 34 may generate a drive control signal to control the timing of the driving unit 21 and a source control signal to control the driving IC 31. The timing controller 34 may supply the drive control signal to the driving unit 21 and the source control signal to the driving IC 31. According to one or more embodiments, the timing controller 34 may be integrated with the driving IC 31 into a single drive chip, which may be mounted on the substrate 100 and connected to the pad unit 30.

Referring to FIG. 1 and FIG. 3, the display apparatus 1 may include a plurality of pixels 11. More specifically, the display area 10 of the display apparatus 1 may include the plurality of pixels 11. The plurality of pixels 11 may be spaced apart from each other and arranged in rows and columns. They may be arranged in a matrix form on the substrate 100. Each of the plurality of pixels 11 may have a rectangular or square shape, but is not limited thereto. Each pixel may also have a rhombus shape.

Each of the plurality of pixels 11 may include sub-pixels. According to one or more embodiments, each pixel 11 may include a first sub-pixel 12 having a first color, a second sub-pixel 13 having a second color, a third sub-pixel 14 having a third color, and a fourth sub-pixel 15. The first color may be red, the second color may be green, the third color may be blue, and the fourth sub-pixel 15 may be white. As illustrated in FIG. 3, the first sub-pixel 12, the fourth sub-pixel 15, the third sub-pixel 14, and the second sub-pixel 13 may be arranged in the order of red, white, green, and blue along the +Y direction, but this is merely an example. The order of the first, second, third, and fourth colors may be changed as desired.

A plurality of wirings 300 (see FIG. 4) may be disposed on the substrate 100. The wirings 300 may include scan lines, data lines, drive current lines, or low-power lines. Each of the pixels 11 may be defined by some of the wirings 300, such as the scan lines, data lines, and drive current lines or low-power lines. Inside each of the pixels 11, a transistor and a light emitting diode (LED) 140 (see FIG. 4) may be disposed. A high potential voltage may be applied to the drive current line to drive the LED 140. A low potential voltage may be applied to the low-power line. The transistor may be connected to the scan line and the data line.

The plurality of wirings 300 may be disposed on one side or both sides of each of the first sub-pixel 12, the second sub-pixel 13, the third sub-pixel 14, and the fourth sub-pixel 15.

According to one or more embodiments of the present disclosure, the display apparatus 1 may include at least one light slit 200. The light slit 200 may be formed on one or both sides of at least one of the first sub-pixel 12, the second sub-pixel 13, the third sub-pixel 14, and the fourth sub-pixel 15.

Referring to FIG. 3, according to one or more embodiments, the display apparatus 1 may include a pair of light slits 210 formed on both sides of the first sub-pixel 12 having the first color. Alternatively, the display apparatus may include only one light slit formed on one side of the first sub-pixel 12.

According to one or more embodiments, the light slits 210 may be disposed on both sides of the first sub-pixel 12 to increase the luminance of the first sub-pixel 12. The light slits 210 may have the same color as the first sub-pixel 12. The first color may be red. The light slits 210 may compensate for the emitted light amount of the first sub-pixel 12, thereby increasing its luminance. By increasing the luminance of the first sub-pixel 12, the light slits 210 may reduce color shift depending on the viewing angle of the display apparatus 1. For example, if the color shift caused by the viewing angle is in a direction lacking red, the light slits 210 may be formed on both sides of the red sub-pixel 12 to increase its luminance and reduce the viewing angle-dependent color shift.

The light slits 210 may include a first light slit 211 formed on one side of the first sub-pixel 12 and a second light slit 212 formed on the opposite side of the first sub-pixel 12. The first light slit 211 and the second light slit 212 may each have the same length as the first sub-pixel 12. The length of the first sub-pixel 12 and the first light slit 211 and second light slit 212may refer to the dimension in the Z direction in the drawings.

The first light slit 211 and the second light slit 212 may each have a width smaller than the width of the first sub-pixel 12. The width of the first sub-pixel 12 and the first light slit 211 and the second light slit 212 may refer to the dimension in the Y direction in the drawings.

As shown in FIG. 4, the plurality of wirings 300 may be disposed on one or both sides of each of the 15first sub-pixel 12, the second sub-pixel 13, the third sub-pixel 14, and the fourth sub-pixel 15. According to one or more embodiments, the wirings 300 may include a first wiring 311 disposed on one side of the first sub-pixel 12 and a second wiring 312 disposed on the opposite side.

The first wiring 311 may include a pair of wiring portions 311a and 311b spaced apart from each other in the first direction. The first slit portion 313 may be formed between the pair of wiring portions 311a and 311b and may correspond to a space between them. The first direction may correspond to the Y direction in the drawings.

The second wiring 312 may include a pair of wiring portions 312a and 312b spaced apart from each other in the first direction. A second slit portion 314 may be formed between the wiring portions 312a and 312b.

The pair of light slits 210 formed on both sides of the first sub-pixel 12 may be formed by light passing through the first slit portion 313 of the first wiring 311 and the second slit portion 314 of the second wiring 312. The first light slit 211 may be formed by light passing through the first slit portion 313, and the second light slit 212 may be formed by light passing through the second slit portion 314.

Referring to FIG. 4, the structure of the display apparatus 1 according to one or more embodiments will now be described in detail.

The display apparatus 1 according to one or more embodiments may include a substrate 100, a plurality of wirings 300 disposed on the substrate 100, an interlayer insulating layer 120 disposed on the substrate 100 to cover the plurality of wirings 300, a planarization layer 130 disposed on the interlayer insulating layer 120 and a light emitting diode (LED) 140 disposed on the planarization layer 130. The display apparatus 1 may further include a buffer layer 110 disposed below the plurality of wirings 300 and formed on the substrate 100.

The substrate 100 may include an insulating material such as glass, quartz, or a polymer resin. According to one or more embodiments, the buffer layer 110 may be formed on the substrate 100 and may cover one surface of the substrate 100. The buffer layer 110 may be disposed on the substrate 100 to protect the transistor and the LED 140 from moisture penetrating through the substrate 100. The buffer layer 110 may be formed of a single layer or a plurality of alternately stacked inorganic films. For example, the buffer layer 110 may include at least one of silicon oxide (SiO₂), silicon nitride (SiN), or silicon oxynitride (SiON), and may be a multilayer structure with alternating layers of these materials. However, it is not limited thereto. The buffer layer 110 may be omitted in some embodiments.

In each of the pixels 11, a transistor may be disposed in a region spaced apart from the plurality of first sub-pixel 12, the second sub-pixel 13, the third sub-pixel 14, and the fourth sub-pixel 15. For example, referring to FIG. 3, the transistor may be disposed in a region spaced in the –Z direction from the first sub-pixel 12, the second sub-pixel 13, the third sub-pixel 14, and the fourth sub-pixel 15. The transistor may be disposed on the buffer layer 110 and may include an active layer, a gate electrode, a source electrode, and a drain electrode.

Referring to FIG. 4, the plurality of wirings 300 may be disposed on the buffer layer 110. As mentioned above, the buffer layer may be omitted, in which case the wirings may be directly formed on the substrate. A current may flow through the plurality of wirings 300, and the wirings may be formed of a conductive material.

According to one or more embodiments, the wirings 300 may include a first wiring 311 disposed on one side of the first sub-pixel 12 and a second wiring 312 disposed on the opposite side. The first wiring 311 may be disposed at one side of a first anode electrode 151, which will be described below. The second wiring 312 may also be disposed at the opposite side of the first anode electrode 151.

The first wiring 311 may include a pair of wiring portions 311a and 311b, formed by dividing at least a portion of the first wiring 311 into two branches. The pair of wiring portions 311a and 311b may be spaced apart from each other in a first direction. A first slit portion 313 may be defined between the pair of wiring portions 311a and 311b. The first slit portion 313 may refer to the spaced region between the wiring portions.

The second wiring 312 may include a pair of wiring portions 312a and 312b, formed by dividing at least a portion of the second wiring 312 into two branches. The pair of wiring portions 312a and 312b may be spaced apart from each other in the first direction. A second slit portion 314 may be defined between the pair of wiring portions 312a and 312b. The second slit portion 314 may refer to the spaced region between the wiring portions.

An interlayer insulating layer 120 may be disposed on the plurality of wirings 300. The interlayer insulating layer 120 may be configured to cover the plurality of wirings 300 and the buffer layer 110. The interlayer insulating layer 120 may be formed to include an insulating material. The interlayer insulating layer 120 may include an inorganic film such as silicon oxide or silicon nitride. The interlayer insulating layer 120 may also be referred to as a protective layer, a protection film, a passivation layer, or a passivation film.

According to one or more embodiments, the display apparatus 1 may be a bottom-emission type display device. In other words, light emitted from the light emitting diode 140 disposed on an upper side of the substrate 100 may pass through the substrate 100 and be emitted toward a lower side of the substrate 100. The upper side of the substrate 100 may correspond to the –X direction in FIG. 4, and the lower side of the substrate 100 may correspond to the +X direction in FIG. 4

Referring to FIG. 4, a color filter may be disposed on at least a portion of the interlayer insulating layer 120. More specifically, a first color filter 12a having a first color may be disposed on the first wiring 311 and the second wiring 312. The first color may be red.

A planarization layer 130 may be disposed on the first color filter 12a. In the case of the fourth sub-pixel 15, where no color filter is provided, the planarization layer 130 may be directly disposed on the interlayer insulating layer 120. The planarization layer 130 may be provided to planarize steps caused by the plurality of wirings 300 and transistors. In other words, due to the presence of color filters or transistors, the surface of the substrate 100 may not be uniform in height, and the planarization layer 130 may be provided to flatten such surface. The planarization layer 130 may be formed to include an organic material. For example, the planarization layer 130 may include at least one organic material selected from acryl resin, epoxy resin, phenolic resin, polyamic resin, and polyimide resin. The planarization layer 130 may also prevent outgassing from the color filters disposed in the respective sub-pixels from reaching the light emitting diode 140 disposed on the planarization layer 130.

The display apparatus 1 may include a light emitting diode 140 disposed on the planarization layer 130. The light emitting diode 140 may include an anode electrode 150, an organic light emitting layer 160, and a cathode electrode 170.

The anode electrode 150 may be disposed on the planarization layer 130. In the case of a top-emission type, the anode electrode may include a metal material having high reflectivity. For example, the anode electrode may include at least one of Ag (silver), Al (aluminum), Ni (nickel), or Cu (copper). In the case of a bottom-emission type, the anode electrode may include a transparent conductive material. For example, the anode electrode may include at least one of indium zinc oxide (IZO) and indium tin oxide (ITO).

A pixel defining layer 180 may be disposed at an edge of the anode electrode 150. The pixel defining layer 180 may be formed to cover the edge of the anode electrode 150 on the planarization layer 130 to define the emission region of each sub-pixel. The pixel defining layer 180 may include an opening to expose the anode electrode 150, and the opening may define the emission region of each sub-pixel. The pixel defining layer 180 may include at least one organic material selected from acryl resin, epoxy resin, phenolic resin, polyamic resin, and polyimide resin. Like the planarization layer 130, the pixel defining layer 180 may also serve to planarize the surface of the substrate 100.

An organic light emitting layer 160 may be disposed on the anode electrode 150 and the pixel defining layer 180. The organic light emitting layer 160 may be provided to cover the entire display area 10 of the substrate 100. The organic light emitting layer 160 may include an organic material. Light may be emitted from the organic light emitting layer 160. Light may not be emitted from the entire area of the organic light emitting layer 160, but may be emitted from an area where the organic light emitting layer 160 overlaps or contacts the anode electrode 150.

Although not specifically illustrated in the drawings, the organic light emitting layer 160 may include multiple layers such as a hole injection layer, a hole transport layer, an emission layer, an electron transport layer, and an electron injection layer to enhance emission efficiency.

A cathode electrode 170 may be disposed on the organic light emitting layer 160 to cover it. According to one or more embodiments, since the display apparatus 1 is of the bottom-emission type, the cathode electrode 170 may be formed to include a metal material having high reflectivity. Accordingly, light emitted from the organic light emitting layer 160 may be reflected by the cathode electrode 170 toward the substrate 100.

Each of the plurality of first sub-pixel 12, the second sub-pixel 13, the third sub-pixel 14, and the fourth sub-pixel 15 may include the light emitting diode 140. That is, each region of the plurality of first sub-pixel 12, the second sub-pixel 13, the third sub-pixel 14, and the fourth sub-pixel 15 may include the anode electrode 150, the organic light emitting layer 160, and the cathode electrode 170.

Referring to FIG. 4, the first wiring 311 may be disposed on one side of a first anode electrode 151, which is part of the anode electrode 150 and defines the emission region of the first sub-pixel 12. The second wiring 312 may be disposed on the opposite side of the first anode electrode 151. The first color filter 12a may be disposed on the first wiring 311 and the second wiring 312. A first pixel defining layer 181 may be disposed at one edge of the first anode electrode 151 as part of the pixel defining layer 180. A second pixel defining layer 182 may be disposed at the opposite edge of the first anode electrode 151. The exposed portion of the first anode electrode 151 between the first pixel defining layer 181 and the second pixel defining layer 182 may define the emission region of the first sub-pixel 12.

Light emitted from the organic light emitting layer 160 overlapping or contacting the first anode electrode 151 may pass through the planarization layer 130, the first color filter 12a, the interlayer insulating layer 120, the buffer layer 110, and the substrate 100, and may be emitted forward through the substrate 100. The front of the substrate 100 may correspond to the +X direction in FIG. 4.

Since the wirings 300 are formed of a metal material having high conductivity, they also have high reflectivity. Accordingly, light emitted from the organic light emitting layer 160 toward the wirings 300 may be reflected by the wirings 300 rather than transmitted through them.

According to one or more embodiments of the present disclosure, at least a portion of the wirings 300 may be divided into two branches to form the first slit portion 313 and the second slit portion 314, and light passing through the first slit portion 313 and the second slit portion 314 may form first light slit 211 and the second light slit 212. Since the first light slit 211 and the second light slit 212 are formed by light passing through the first color filter 12a and the first slit portions 313 and the second slit portion 314, the light slits may have the first color of the first color filter 12a. Therefore, the first light slit 211 and the second light slit 212 may supplement the light amount of the first color of the first sub-pixel 12. The first light slit 211 and the second light slit 212 may compensate for color shift depending on the viewing angle by supplementing the amount of red light when the display apparatus 1 is viewed from the side.

Referring to FIG. 4, a portion of light emitted from the organic light emitting layer 160 overlapping or contacting the first anode electrode 151 may be reflected by the cathode electrode 170 without passing through the first pixel defining layer 181, and may pass through the first color filter 12a, the first slit portion 313, and the substrate 100 to form the first light slit 211. Similarly, another portion of light may be reflected by the cathode electrode 170 without passing through the second pixel defining layer 182, and may pass through the first color filter 12a, the second slit portion 314, and the substrate 100 to form the second light slit 212.

According to one or more embodiments, the first light slit 211 or the first slit portion 313 may be formed at a position corresponding to the first pixel defining layer 181. The second light slit 212 or the second slit portion 314 may be formed at a position corresponding to the second pixel defining layer 182. The first light slit 211 and the second light slit 212 may extend along a second direction perpendicular to the first direction. The second direction may correspond to the Z direction in FIG. 3.

The width of the first light slit 211 may be increased by reducing the width of the first pixel defining layer 181 disposed on the first slit portion 313. The width of the first light slit 211 may refer to its length in the Y direction of FIG. 3. The width of the first pixel defining layer 181 may also refer to its length in the Y direction of FIG. 3.

The width of the second light slit 212 may be increased by reducing the width of the second pixel defining layer 182 disposed on the second slit portion 314. The width of the second light slit 212 may refer to its length in the Y direction of FIG. 3. The width of the second pixel defining layer 182 may also refer to its length in the Y direction of FIG. 3.

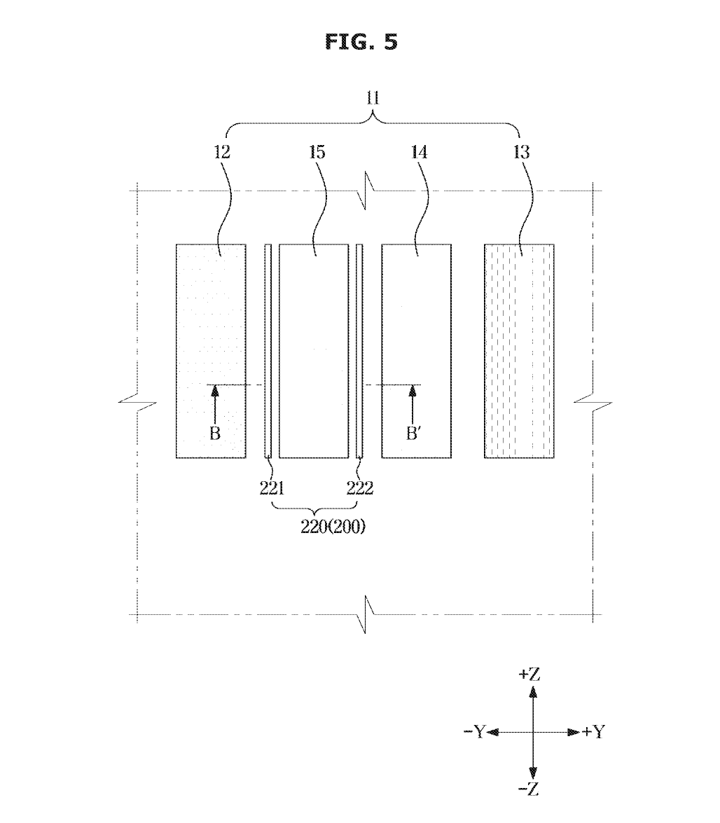

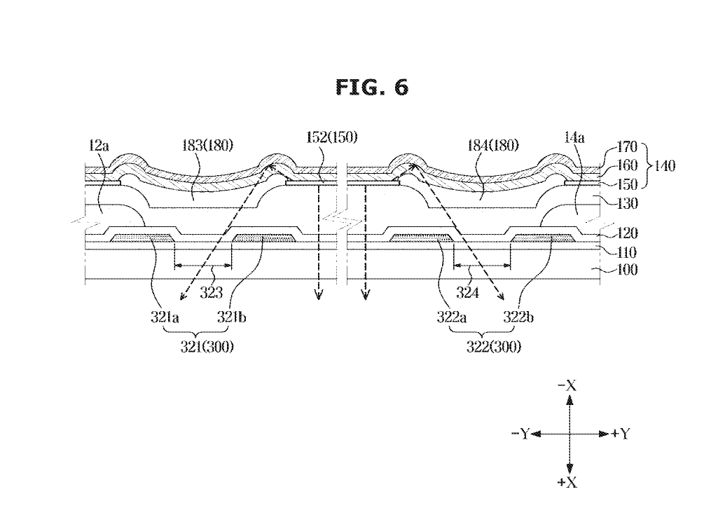

FIG. 5 is an enlarged view of a pixel of the display apparatus according to one or more embodiments, and FIG. 6 is a cross-sectional view taken along the line B–B′ of FIG. 5.

Referring to FIG. 5 and FIG. 6, the display apparatus 1 according to one or more embodiments may include a third light slit 221 and a fourth light slit 222 formed on both sides of the fourth sub-pixel 15. The fourth sub-pixel 15 may emit white light. Accordingly, the third light slit 221 and the fourth light slit 222 may form white slit light. The third light slit 221 and the fourth light slit 222 may supplement the amount of white light of the fourth sub-pixel 15.

Referring to FIG. 6, the fourth sub-pixel 15 may not include a color filter. In other words, no color filter may be disposed below a second anode electrode 152 defining the emission region of the fourth sub-pixel 15, and only the planarization layer 130 may be disposed thereunder. An interlayer insulating layer 120 may be disposed directly under the planarization layer 130.

A third pixel defining layer 183 may be disposed at one edge of the second anode electrode 152 defining the emission region of the fourth sub-pixel 15. A fourth pixel defining layer 184 may be disposed at the opposite edge of the second anode electrode 152.

A third wiring 321 may be disposed under the third pixel defining layer 183. At least a portion of the third wiring 321 may be split into two branches to form a pair of wiring portions 321a and 321b spaced apart in a first direction. A third slit portion 323 may be formed between the pair of wiring portions 321a and 321b.

A fourth wiring 322 may be disposed under the fourth pixel defining layer 184. At least a portion of the fourth wiring 322 may be split into two branches to form a pair of wiring portions 322a and 322b spaced apart in the first direction. A fourth slit portion 324 may be formed between the pair of wiring portions 322a and 322b.

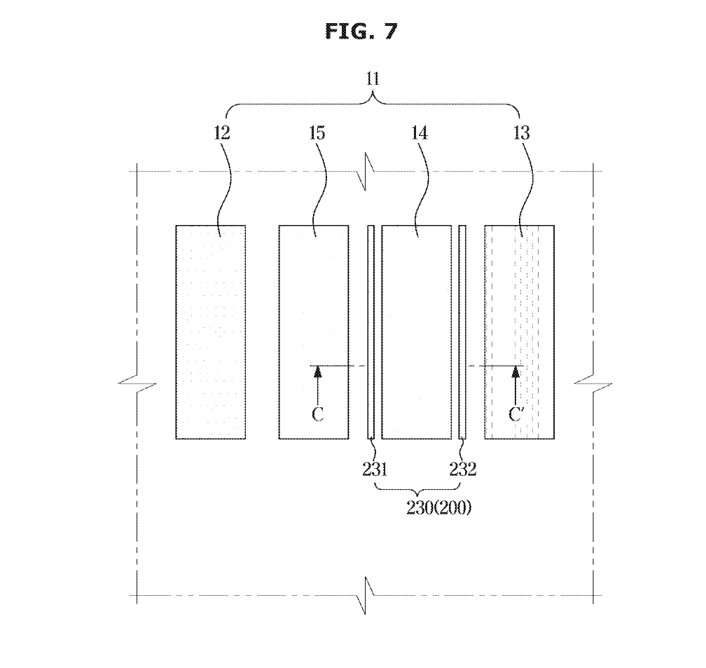

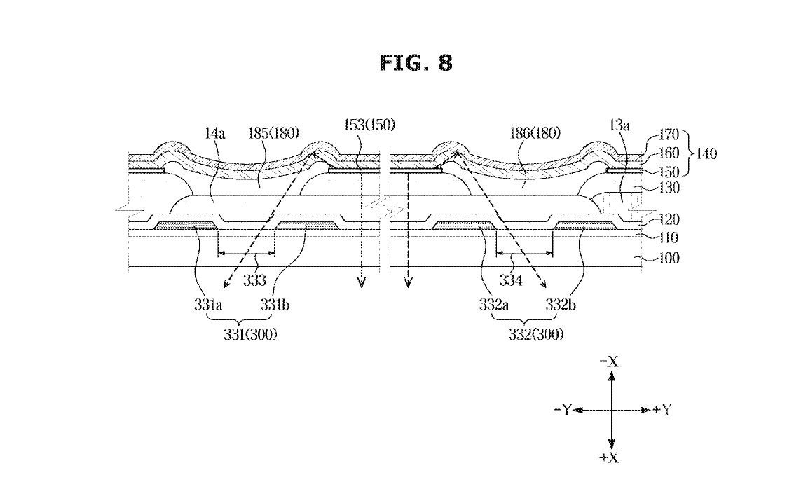

FIG. 7 is an enlarged view of a pixel of the display apparatus according to one or more embodiments, and FIG. 8 is a cross-sectional view taken along the line C–C′ of FIG. 7.

Referring to FIG. 7 and FIG. 8, the display apparatus 1 according to one or more embodiments may include a fifth light slit 231 and a sixth light slit 232 formed on both sides of the third sub-pixel 14. The third sub-pixel 14 may emit blue light. Accordingly, the fifth light slit 231 and the sixth light slit 232 may form blue slit light. The fifth light slit 231 and the sixth light slit 232 may supplement the amount of blue light of the third sub-pixel 14. The fifth light slit 231 and the sixth light slit 232 may compensate for color shift depending on the viewing angle by supplementing the amount of blue light when the display apparatus 1 is viewed from the side.

Referring to FIG. 8, the third sub-pixel 14 may include a third color filter 14a. A third color filter 14a may be disposed under a third anode electrode 153 defining the emission region of the third sub-pixel 14, and a planarization layer 130 may be disposed under the third color filter 14a.

A fifth pixel defining layer 185 may be disposed at one edge of the third anode electrode 153 defining the emission region of the third sub-pixel 14. A sixth pixel defining layer 186 may be disposed at the opposite edge of the third anode electrode 153.

A fifth wiring 331 may be disposed under the fifth pixel defining layer 185. At least a portion of the fifth wiring 331 may be split into two branches to form a pair of wiring portions 331a and 331b spaced apart in the first direction. A fifth slit portion 333 may be formed between the pair of wiring portions 331a and 331b.

A sixth wiring 332 may be disposed under the sixth pixel defining layer 186. At least a portion of the sixth wiring 332 may be split into two branches to form a pair of wiring portions 332a and 332b spaced apart in the first direction. A sixth slit portion 334 may be formed between the pair of wiring portions 332a and 332b.

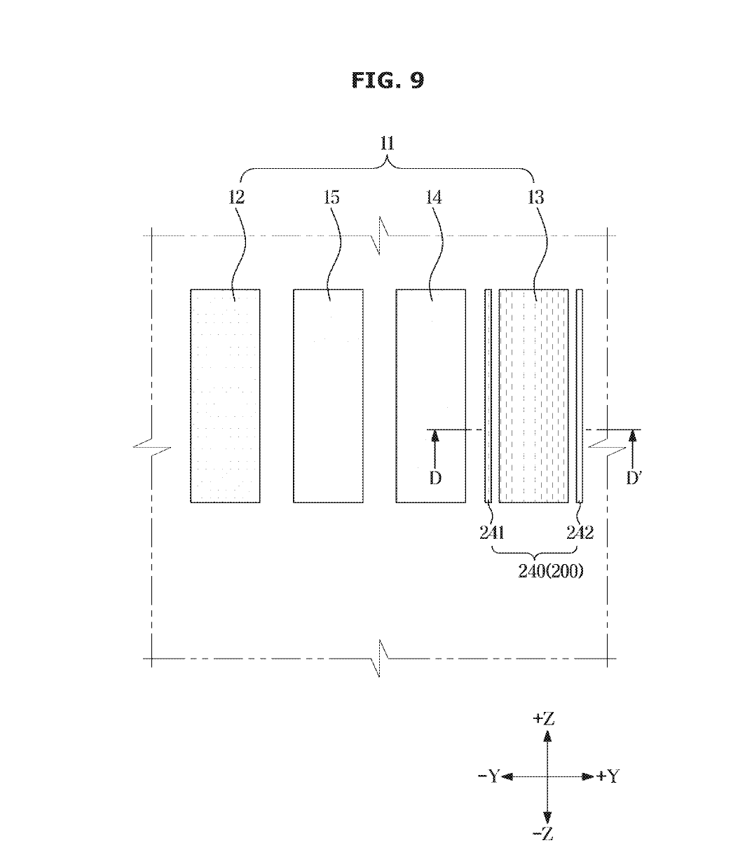

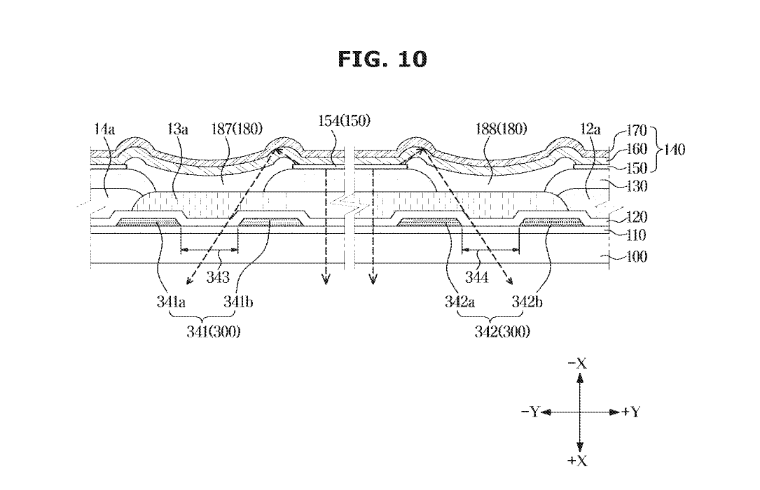

FIG. 9 is an enlarged view of a pixel of the display apparatus according to one or more embodiments, and FIG. 10 is a cross-sectional view taken along the line D–D′ of FIG. 9.

Referring to FIG. 9 and FIG. 10, the display apparatus 1 according to one or more embodiments may include a seventh light slit 241 and an eighth light slit 242 formed on both sides of the second sub-pixel 13. The second sub-pixel 13 may emit green light. Accordingly, the seventh light slit 241 and the eighth light slit 242 may form green slit light. The seventh light slit 241 and the eighth light slit 242 may supplement the amount of green light of the second sub-pixel 13. The seventh light slit 241 and the eighth light slit 242 may compensate for color shift depending on the viewing angle by supplementing the amount of green light when the display apparatus 1 is viewed from the side.

Referring to FIG. 10, the second sub-pixel 13 may include a second color filter 13a. A second color filter 13a may be disposed under a fourth anode electrode 154 defining the emission region of the second sub-pixel 13, and a planarization layer 130 may be disposed under the second color filter 13a.

A seventh pixel defining layer 187 may be disposed at one edge of the fourth anode electrode 154 defining the emission region of the second sub-pixel 13. An eighth pixel defining layer 188 may be disposed at the opposite edge of the fourth anode electrode 154.

A seventh wiring 341 may be disposed under the seventh pixel defining layer 187. At least a portion of the seventh wiring 341 may be split into two branches to form a pair of wiring portions 341a and 341b spaced apart in the first direction. A seventh slit portion 343 may be formed between the pair of wiring portions 341a and 341b.

An eighth wiring 342 may be disposed under the eighth pixel defining layer 188. At least a portion of the eighth wiring 342 may be split into two branches to form a pair of wiring portions 342a and 342b spaced apart in the first direction. An eighth slit portion 344 may be formed between the pair of wiring portions 342a and 342b.

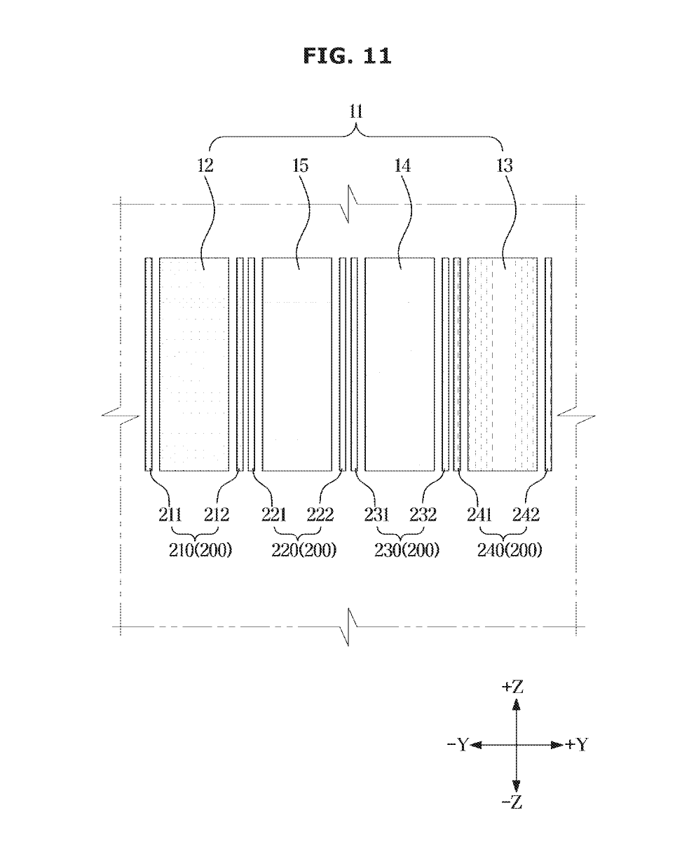

FIG. 11 is an enlarged view of a pixel of the display apparatus according to one or more embodiments.

Referring to FIG. 11, each pixel 11 of the display apparatus 1 according to one or more embodiments may include a first light slit 211 and a second light slit 212 formed on both sides of the first sub-pixel 12, a third light slit 221 and a fourth light slit 222 formed on both sides of the fourth sub-pixel 15, a fifth light slit 231 and a sixth light slit 232 formed on both sides of the third sub-pixel 14, and a seventh light slit 241 and an eighth light slit 242 formed on both sides of the second sub-pixel 13.

Light slits may be formed on one or both sides of two of the first sub-pixel 12, the second sub-pixel 13, the third sub-pixel 14, and the fourth sub-pixel 15. In addition, light slits may be formed on one or both sides of three of the first sub-pixel 12, the second sub-pixel 13, the third sub-pixel 14, and the fourth sub-pixel 15.

According to one or more embodiments, the display apparatus may include: a substrate; and a pixel disposed on the substrate, the pixel including a first sub-pixel, a second sub-pixel, a third sub-pixel, and a fourth sub-pixel arranged to be spaced apart from one another in a first direction. The display apparatus may further include a wiring disposed on the substrate on one side of at least one of the first, second, third, and fourth sub-pixels; and a light slit formed on one side of the at least one of the first to fourth sub-pixels to increase light amount thereof. The light slit may be formed by light passing through a slit portion formed in the wiring.

The wiring may include a pair of wiring portions spaced apart in the first direction as at least a portion of the wiring.

The slit portion may be formed between the pair of wiring portions.

The light slit may include a first light slit formed on one side of the at least one of the first to fourth sub-pixels, and a second light slit formed on the opposite side of the at least one of the first to fourth sub-pixels.

The wiring may include a first wiring forming the first light slit on one side of the at least one of the first to fourth sub-pixels and a second wiring forming the second light slit on the other side of the at least one of the first to fourth sub-pixels.

The display apparatus may further include an interlayer insulating layer disposed on the substrate and the wiring so as to cover the wiring.

The display apparatus may further include a planarization layer disposed on the interlayer insulating layer.

Each of the first, second, third, and fourth sub-pixels may include an anode electrode disposed on the planarization layer.

Each of the first, second, third, and fourth sub-pixels may include a pixel defining layer formed to cover the edge of the anode electrode and the edge of the planarization layer adjacent to the anode electrode.

Each of the first, second, third, and fourth sub-pixels may include an organic light emitting layer disposed on the anode electrode and the pixel defining layer.

Each of the first, second, third, and fourth sub-pixels may include a cathode electrode disposed on the organic light emitting layer.

The first sub-pixel may include a first color filter having a first color, which is disposed on the substrate and under the pixel defining layer and the planarization layer.

The second sub-pixel may include a second color filter having a second color, which is disposed on the substrate and under the pixel defining layer and the planarization layer.

The third sub-pixel may include a third color filter having a third color, which is disposed on the substrate and under the pixel defining layer and the planarization layer.

The fourth sub-pixel may be configured such that an interlayer insulating layer is disposed under the planarization layer and the pixel defining layer without a color filter.

When the first color filter is disposed to cover the slit portion of the wiring, the light slit may have the first color.

When the second color filter is disposed to cover the slit portion of the wiring, the light slit may have the second color.

When the third color filter is disposed to cover the slit portion of the wiring, the light slit may have the third color.

When there is no color filter covering the slit portion of the wiring, the light slit may have the same color as the light emitted from the organic light emitting layer.

The light slit may be formed by light emitted from the organic light emitting layer passing through the slit portion of the wiring and the substrate.

The light slit may be formed at a position corresponding to the pixel defining layer and may extend in a second direction perpendicular to the first direction.

The width of the light slit may increase by reducing the width of the pixel defining layer disposed on the slit portion.

The light slit may include a pair of light slits disposed on both sides of any one of the first, second, third, and fourth sub-pixels.

The light slit may include a plurality of light slits disposed on both sides of each of the first sub-pixel, the second sub-pixel, the third sub-pixel, and the fourth sub-pixel.

When a color shift occurs in the display apparatus due to insufficient light amount of at least one of the first color, the second color, or the third color, the light slit may be configured to increase the light amount of the corresponding color, thereby reducing color shift depending on the viewing angle of the display apparatus.

According to an embodiment, the display apparatus may include: a substrate; a wiring disposed on the substrate and including a slit portion; an interlayer insulating layer disposed on the substrate to cover the wiring; a planarization layer disposed on the interlayer insulating layer; an anode electrode disposed on the planarization layer; a pixel defining layer disposed to cover the edge of the anode electrode and the adjacent edge of the planarization layer; an organic light emitting layer disposed on the anode electrode and the pixel defining layer; a cathode electrode disposed on the organic light emitting layer; and a light slit formed by light passing through the slit portion of the wiring and the substrate.

The wiring may include a pair of wiring portions provided on both sides of the slit portion as at least a portion of the wiring.

The display apparatus may include a pixel disposed on the substrate, the pixel including a first sub-pixel, a second sub-pixel, and a third sub-pixel arranged to be spaced apart in a first direction.

Each of the first, second, and third sub-pixels may include the anode electrode, the pixel defining layer, the organic light emitting layer, and the cathode electrode.

The first sub-pixel may include a first color filter having a first color, which is disposed under the pixel defining layer and the planarization layer on the substrate.

The second sub-pixel may include a second color filter having a second color, which is disposed under the pixel defining layer and the planarization layer on the substrate.

The third sub-pixel may include a third color filter having a third color, which is disposed under the pixel defining layer and the planarization layer on the substrate.

The light slit may be formed at a position corresponding to the pixel defining layer.

The width of the light slit may increase by reducing the width of the pixel defining layer disposed on the slit portion.

According to the concept of the present disclosure, a display apparatus that reduces color shift depending on the viewing angle may be provided by including a light slit.

According to the concept of the present disclosure, a display apparatus may be provided in which at least a portion of the wiring disposed between sub-pixels is divided into two spaced-apart wiring portions, and a light slit is formed between the two wiring portions.

Although specific embodiments have been illustrated and described above, the present invention is not limited to the embodiments described above, and it will be apparent to those skilled in the art that various changes and modifications can be made without departing from the gist of the technical spirit of the invention described in the claims below.

What is claimed is:

1. A display apparatus comprising:
a substrate;
a pixel disposed on the substrate, the pixel comprising a first sub-pixel, a second sub-pixel, a third sub-pixel, and a fourth sub-pixel that are spaced apart from each other in a first direction;
a wiring disposed on the substrate at a side of at least one sub-pixel of the first sub-pixel, the second sub-pixel, the third sub-pixel, and the fourth sub-pixel; and
a light slit formed at the side of the at least one sub-pixel and through which a light of the at least one sub-pixel is configured to be emitted by the light being passed through a slit portion formed in the wiring.

2. The display apparatus of claim 1, wherein the wiring comprises a pair of wiring portions spaced apart in the first direction, the pair of wiring portions being at least a portion of the wiring, and
the slit portion is formed between the pair of wiring portions.

3. The display apparatus of claim 1, wherein the light slit comprises:
a first light slit formed at a first side of the at least one sub-pixel; and
a second light slit formed at a second side of the at least one sub-pixel.

4. The display apparatus of claim 3, wherein the wiring comprises:
a first wiring disposed on the substrate at the first side of the at least one sub-pixel and in which the first light slit is formed; and
a second wiring disposed on the substrate at the second side of the at least one sub-pixel and in which the second light slit is formed.

5. The display apparatus of claim 1, further comprising:
an interlayer insulating layer disposed on the substrate and the wiring, and covering the wiring; and
a planarization layer disposed on the interlayer insulating layer.

6. The display apparatus of claim 5, wherein each of the first sub-pixel, the second sub-pixel, the third sub-pixel, and the fourth sub-pixel comprises:
an anode electrode disposed on the planarization layer;
a pixel defining layer covering an edge of the anode electrode and an edge of the planarization layer adjacent to the edge of the anode electrode;
an organic light emitting layer disposed on the anode electrode and the pixel defining layer; and
a cathode electrode disposed on the organic light emitting layer.

7. The display apparatus of claim 6, wherein the first sub-pixel comprises a first color filter disposed on the substrate and having a first color, the pixel defining layer and the planarization layer being disposed on the first color filter,
wherein the second sub-pixel comprises a second color filter disposed on the substrate and having a second color, the pixel defining layer and the planarization layer being disposed on the second color filter,
wherein the third sub-pixel comprises a third color filter disposed on the substrate and having a third color, the pixel defining layer and the planarization layer being disposed on the third color filter, and
wherein the fourth sub-pixel is configured such that the planarization layer and the pixel defining layer are disposed on the interlayer insulating layer, and the fourth sub-pixel without a color filter.

8. The display apparatus of claim 7, wherein, in a case in which the slit portion of the wiring is covered by the first color filter, the light which the light slit is configured to emit has the first color,
wherein, in a case in which the slit portion of the wiring is covered by the second color filter, the light which the light slit is configured to emit has the second color,
wherein, in a case in which the slit portion of the wiring is covered by the third color filter, the light which the light slit is configured to emit has the third color, and
wherein, in a case in which the slit portion of the wiring is not covered by a cover filter, the light which the light slit is configured to emit has a same color as light emitted from the organic light emitting layer.

9. The display apparatus of claim 6, wherein the organic light emitting layer is configured to emit the light through the slit portion of the wiring.

10. The display apparatus of claim 6, wherein the pixel defining layer of at least one of the first sub-pixel, the second sub-pixel, the third sub-pixel, and the fourth sub-pixel is disposed on the light slit,
wherein the one sub-pixel is the at least one of the first sub-pixel, the second sub-pixel, the third sub-pixel, and the fourth sub-pixel, and
wherein the light slit is extended in a second direction perpendicular to the first direction.

11. The display apparatus of claim 6, wherein a width of the light slit increases by reducing a width of the pixel defining layer disposed on the slit portion.

12. The display apparatus of claim 1, further comprising:
a plurality of light slits, including the light slit.

13. The display apparatus of claim 1, further comprising:
a plurality of light slits, including the light slit, at opposite sides of each of the first sub-pixel, the second sub-pixel, the third sub-pixel, and the fourth sub-pixel.

14. The display apparatus of claim 7, wherein the light slit is configured to reduce a color shift, depending on a viewing angle of the display apparatus, by emitting the light as with one of the first color, the second color and the third color.

15. A display apparatus comprising:
a substrate;
a wiring disposed on the substrate and comprising a slit portion;
an interlayer insulating layer disposed on the substrate and covering the wiring;
a planarization layer disposed on the interlayer insulating layer;
an anode electrode disposed on the planarization layer;
a pixel defining layer covering an edge of the anode electrode and an adjacent edge of the planarization layer;
an organic light emitting layer disposed on the anode electrode and the pixel defining layer;
a cathode electrode disposed on the organic light emitting layer; and
a light slit configured to pass light through a slit portion of the wiring and the substrate.

16. The display apparatus of claim 15, wherein the wiring comprises a pair of wiring portions at both sides of the slit portion, the pair of wiring portions being as at least a portion of the wiring.

17. The display apparatus of claim 15, further comprising a pixel disposed on the substrate, the pixel comprising a first sub-pixel, a second sub-pixel, and a third sub-pixel that are spaced apart from each other in a first direction.

18. The display apparatus of claim 17, wherein each of the first sub-pixel, the second sub-pixel, and the third sub-pixel comprises the anode electrode, the pixel defining layer, the organic light emitting layer, and the cathode electrode.

19. The display apparatus of claim 18, wherein the first sub-pixel comprises a first color filter disposed on the substrate and having a first color, the pixel defining layer and the planarization layer being disposed on the first color filter,
wherein the second sub-pixel comprises a second color filter disposed on the substrate and having a second color, the pixel defining layer and the planarization layer being disposed on the second color filter, and
wherein the third sub-pixel comprises a third color filter disposed on the substrate and having a third color, the pixel defining layer and the planarization layer being disposed on the third color filter.

20. The display apparatus of claim 18, wherein the light slit is formed at a position corresponding to the pixel defining layer.
